(19) United States
(12) Patent Application Publication
(10) Pub. No.: US 2009/0160008 A1
(43) Pub. Date: Jun. 25, 2009

(54) SEMICONDUCTOR DEVICE AND METHOD OF MANUFACTURING THE SAME

(76) Inventors: Hirokazu Fujiwara, Nishikamo-gun (JP); Masaki Konishi, Toyota-shi (JP); Eiichi Okuno, Mizuho-shi (JP)

Correspondence Address: KENYON & KENYON LLP, 1500 K STREET N.W., SUITE 700, WASHINGTON, DC, 20005, US

(21) Appl. No.: 12/343,714

(22) Filed: Dec. 24, 2008

(30) Foreign Application Priority Data
Dec. 25, 2007 (JP) 2007-331621

(51) Int. Cl. H01L 29/47; H01L 21/441

(52) U.S. Cl. 257/471; 438/571; 257/E29.148; 257/E21.477

(57) ABSTRACT

A semiconductor device that includes an n-type semiconductor substrate and an upper electrode formed on an upper face of the semiconductor substrate and a method of manufacturing the semiconductor device are provided. A p-type semiconductor region is repeatedly formed in the semiconductor substrate in at least one direction parallel to the substrate plane so as to be exposed on an upper face of the semiconductor substrate. The upper electrode includes a metal electrode portion; and a semiconductor electrode portion made of a semiconductor material whose band gap is narrower than that of the semiconductor substrate. The semiconductor electrode portion is provided on each p-type semiconductor region exposed on the upper face of the semiconductor substrate. The metal electrode portion is in Schottky contact with an n-type semiconductor region exposed on the upper face of the semiconductor substrate, and is in ohmic contact with the semiconductor electrode portion.

### INCORPORATION BY REFERENCE

The disclosure of Japanese Patent Application No. 2007-331621 filed on Dec. 25, 2007 including the specification, drawings and abstract is incorporated herein by reference in its entirety.

### BACKGROUND OF THE INVENTION

1. Field of the Invention

The invention relates to a semiconductor device and a method of manufacturing the same. More specifically, the invention relates to a semiconductor device in which a Schottky barrier diode structure and a p-n diode structure are formed, and a method of manufacturing the semiconductor device.

2. Description of the Related Art

Published Japanese Translation of PCT application No. 2003-510817 (JP-A-2003-510817) describes a semiconductor device function barrier Schottky diode) in which a Schottky barrier diode structure and a p-n diode structure are alternately formed. The semiconductor device includes an n-type semiconductor substrate and an upper electrode formed on the upper face of the semiconductor substrate. In the semiconductor substrate, p-type semiconductor regions are repeatedly formed in one direction parallel to the substrate plane so as to be exposed on the upper face of the semiconductor substrate. The upper electrode has a junction layer made of an alloy of aluminum and nickel. The junction layer of the upper electrode is in Schottky contact with n-type semiconductor regions that are exposed on the upper face of the semiconductor substrate, and is also in ohmic contact with p-type semiconductor regions that are exposed on the upper face of the semiconductor substrate. When the semiconductor device of this type is reverse-biased, a depletion layer generated at each p-n diode structure spreads to the Schottky barrier diode structure. This improves leakage current and low surge resistance in the Schottky barrier diode structure. On the other hand, when the above semiconductor device is forward-biased, low on-resistance and high-speed reverse recovery time may be achieved by the Schottky barrier diode structures.

In the technology described in JP-A-2003-510817, the junction layer of the upper electrode, made of a metal material, is in ohmic contact with the p-type semiconductor regions of the semiconductor substrate. In this structure, when a semiconductor substrate having a wide band gap, such as silicon carbide, is, for example, used, contact resistances between the junction layer of the upper electrode and the p-type semiconductor regions increase. As a result, on-resistance (voltage drop when the semiconductor device is forward-biased) increases.

### SUMMARY OF THE INVENTION

The invention provides a technology for making it possible to suppress an increase in on-resistance even when a semiconductor substrate having a wide band gap is used.

An aspect of the invention provides a semiconductor device. The semiconductor device includes an n-type semiconductor substrate and an upper electrode formed on an upper face of the semiconductor substrate. A p-type semiconductor region is repeatedly formed in the semiconductor substrate in at least one direction parallel to the substrate plane so as to be exposed on an upper face of the semiconductor substrate. The upper electrode includes a metal electrode portion made of a metal material; and a semiconductor electrode portion made of a semiconductor material whose band gap is narrower than that of the semiconductor substrate. The semiconductor electrode portion is provided on each p-type semiconductor region that is exposed on the upper face of the semiconductor substrate. The metal electrode portion is in Schottky contact with an n-type semiconductor region that is exposed on the upper face of the semiconductor substrate, and is in ohmic contact with the semiconductor electrode portion.

According to the above semiconductor device, the semiconductor electrode portion made of a semiconductor material whose band gap is narrower than that of the semiconductor substrate is provided between the metal electrode portion of the upper electrode, made of a metal material, and each p-type semiconductor region of the semiconductor substrate. Thus, in comparison with the case in which the metal electrode portion of the upper electrode is directly connected to each p-type semiconductor region of the semiconductor substrate, it is possible to decrease a contact resistance between the upper electrode and each p-type semiconductor region of the semiconductor substrate. With the above semiconductor device, even when a semiconductor substrate having a wide band gap is used, it is possible to suppress an increase in on-resistance of the semiconductor device.

In the above semiconductor device, the semiconductor substrate may be made of silicon carbide. Silicon carbide has a relatively wide band gap. Thus, when the semiconductor substrate is made of silicon carbide, it is possible to remarkably decrease the on-resistance of the semiconductor device owing to the technology according to the aspect of the invention.

In the above semiconductor device, the semiconductor electrode portion may be made of germanium-silicon. When the material of the semiconductor electrode portion is germanium-silicon, it is possible to relatively easily form the semiconductor electrode portion.

In the above semiconductor device, at least part of a surface of each p-type semiconductor region may be recessed from the upper face of the semiconductor substrate. The contact resistance between the upper electrode and each p-type semiconductor region of the semiconductor substrate varies depending on the impurity concentration of each p-type semiconductor region. That is, when the impurity concentration is low at the surface layer portion of each p-type semiconductor region, the contact resistance between the upper electrode and each p-type semiconductor region of the semiconductor substrate increases. In terms of this point, there is a possibility that, at the surface layer portion of each p-type semiconductor region, impurities may be diffused outward in a process of manufacturing the semiconductor device and then the impurity concentration may be decreased. For the above reason, when the surface layer portion of each p-type semiconductor region is recessed prior to formation of the upper electrode, it is possible to prevent an increase in contact resistance between the upper electrode and each p-type semiconductor region.

In the above semiconductor device, the semiconductor substrate may include, in the order from a side adjacent to a lower face of the semiconductor substrate, a high-concentration n-type semiconductor layer that contains a high concentration of n-type impurities; a medium-concentration n-type semiconductor layer that contains a medium concentration of n-type impurities; and a low-concentration n-type semiconductor layer that contains a low concentration of n-type impurities. In this case, each p-type semiconductor region may be formed in the low-concentration n-type semiconductor layer of the semiconductor substrate. With the above structure, a depletion layer tends to spread from a pn junction plane between the low-concentration n-type semiconductor layer and each p-type semiconductor region and, therefore, leakage current is further suppressed when the semiconductor device is reverse-biased. In addition, the interval between the adjacent p-type semiconductor regions may be increased and, therefore, it is possible to increase the area in which the upper electrode is in Schottky contact with the semiconductor substrate.

Another aspect of the invention provides a method of manufacturing a semiconductor device, which includes the following steps. The method of manufacturing the semiconductor device includes a substrate preparation step of preparing an n-type semiconductor substrate; a p-type region formation step of forming a p-type semiconductor region repeatedly in the semiconductor substrate in at least one direction parallel to the substrate plane so as to be exposed on an upper face of the semiconductor substrate; and an electrode formation step of forming an upper electrode on the upper face of the semiconductor substrate. The upper electrode, which is formed in the electrode formation step, includes a metal electrode portion made of a metal material; and a semiconductor electrode portion made of a semiconductor material whose band gap is narrower than that of the -semiconductor substrate. The semiconductor electrode portion is provided on each p-type semiconductor region that is exposed on the upper face of the semiconductor substrate. The metal electrode portion is in Schottky contact with an n-type semiconductor region that is exposed on the upper face of the semiconductor substrate, and is in ohmic contact with the semiconductor electrode portion. According to the above manufacturing method, even when a semiconductor substrate having a wide band gap is used, it is possible to manufacture a semiconductor device whose on-resistance is relatively low.

In the above manufacturing method, the electrode formation step may include a metal electrode film formation step of forming a metal electrode film, which is at least part of the metal electrode portion, on the upper face of the semiconductor substrate; an etching step of removing the metal electrode film formed on each p-type semiconductor region that is exposed on the upper face of the semiconductor substrate; and a semiconductor electrode formation step of forming the semiconductor electrode portion on each p-type semiconductor region that is exposed on the upper face of the semiconductor substrate. In the etching step, at least part of a surface layer portion of each p-type semiconductor region may be further removed continuously to the removal of the metal electrode film. According to the above manufacturing method, the surface layer portion of each p-type semiconductor region whose impurity concentration is often low is removed. Thus, it is possible to suppress the contact resistance between the upper electrode and each p-type semiconductor region of the semiconductor substrate to a relatively low value.

According to the aspects of the invention, it is possible to implement a semiconductor device, particularly, a junction barrier Schottky diode, whose on-resistance is relatively low, using a semiconductor substrate having a wide band gap.

### BRIEF DESCRIPTION OF THE DRAWINGS

The features, advantages, and technical and industrial significance of this invention will be described in the following detailed description of example embodiments of the invention with reference to the accompanying drawings, in which like numerals denote like elements, and wherein:

FIG. 1 is a cross-sectional view that shows the structure of a semiconductor device according to an embodiment of the invention;

FIG. 2 is a cross-sectional view that is taken along the line II-II in FIG. 1;

FIG. 3 is a flowchart that shows the flow of a method of manufacturing the semiconductor device according to the embodiment of the invention;

FIG. 4 is a view that shows a half-finished semiconductor device (step S10);

FIG. 5 is a view that shows a half-finished semiconductor device (step S20 and step S30);

FIG. 6 is a view that shows a half-finished semiconductor device (step S40);

FIG. 7 is a view that shows a half-finished semiconductor device (step S50);

FIG. 8 is a view that shows a half-finished semiconductor device (step S60);

FIG. 9 is a view that shows a half-finished semiconductor device (step S70); and

FIG. 10 is a graph that shows an impurity concentration in a p-type semiconductor region in the depth direction.

### DETAILED DESCRIPTION OF EMBODIMENTS

First, example embodiments of the invention will be listed.
(1) A semiconductor substrate is desirably 4H—SiC (3.2 eV) or 6H—SiC (2.9 eV) with a hexagonal crystal structure. In this case, a semiconductor electrode is desirably made of 3C—SiC (2.2 eV), AIP (2.45 eV), ZnSe (2.5 eV), GaP (2.26 eV), AlAs (2.16 eV), GaAs (1.435 ev), Si (1.12 eV), IuP (1.35 eV), GeSi (1.0 eV), Ge (0.67 eV), or InSb (0.18 eV). Here, the above parenthesized numbers with unit symbol represent band gaps of the respective semiconductor materials. Note that the semiconductor material of the semiconductor substrate is not limited to 4H—SiC; it may be appropriately selected depending on the characteristics required for the semiconductor device. In this case, the semiconductor electrode is made of a semiconductor material having a band gap that is narrower than the semiconductor material of the semiconductor substrate.
(2) A p-type semiconductor region may be formed, for example, in a stripe so as to be repeatedly formed in one direction parallel to the substrate plane. Alternatively, the p-type semiconductor region may also be formed in a lattice so as to be repeatedly formed in two directions parallel to the substrate plane. Alternatively, the p-type semiconductor region may be formed in a honeycomb so as to be repeatedly formed in three directions parallel to the substrate plane.
(3) An upper electrode includes a metal electrode portion made of a metal material and a semiconductor electrode portion made of a semiconductor material. The metal electrode portion includes Schottky electrodes and a main metal electrode. Each of the Schottky electrodes is provided on an n-type semiconductor region that is exposed on the upper face of the semiconductor substrate, and is in Schottky contact with the n-type semiconductor region. The semiconductor electrode portion is provided on each p-type semiconductor region that is exposed on the upper face of the semiconductor substrate. The band gap of the semiconductor material of the semiconductor electrode portion is narrower than the band gap of the semiconductor material of the semiconductor substrate. At least the main metal electrode is in ohmic contact with the semiconductor electrode portion.
(4) An etching process in which a metal electrode film is removed is desirably performed by reactive ion etching. By so doing, it is possible to successively perform removal of the metal electrode film and removal of the surface layer portion of each p-type semiconductor region of the semiconductor substrate.

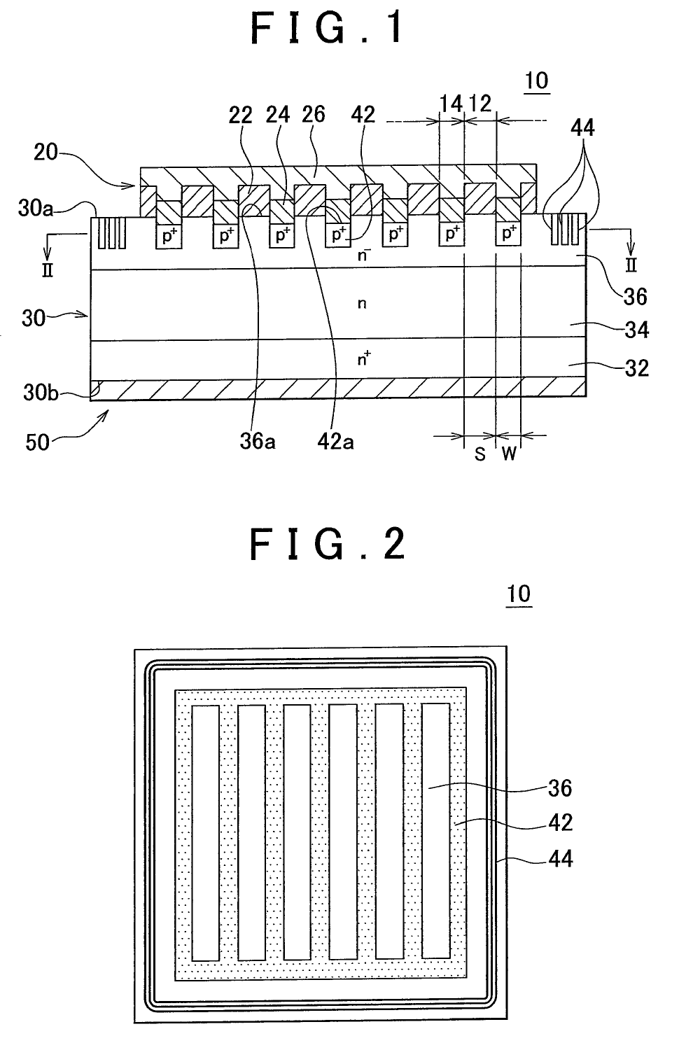

An embodiment of the invention will be described with reference to the accompanying drawings. FIG. 1 is a cross-sectional view that shows the structure of a semiconductor device 10 according to the embodiment of the invention. FIG. 2 is a cross-sectional view that is taken along the line II-II in FIG. 1, and shows the pattern of p-type semiconductor regions 42 formed in the semiconductor device 10. The semiconductor device 10 is a so-called junction barrier Schottky diode (JBS) in which a Schottky barrier diode structure 12 and a p-n diode structure 14 are alternately formed.

As shown in FIG. 1, the semiconductor device 10 mainly includes a semiconductor substrate 30, an upper electrode 20 formed on the upper face 30a of the semiconductor substrate 30, and a lower electrode 50 formed on the lower face 30b of the semiconductor substrate 30. The semiconductor substrate 30 is a crystallization of silicon carbide having a hexagonal crystal structure (typically, 4H—SiC or 6H—SiC). The semiconductor substrate 30 is an n-type semiconductor crystal that is doped with n-type impurities. The semiconductor substrate 30 has, in the order from the side adjacent to the lower face 30b, a contact layer 32 that contains a high concentration of n-type impurities, a drift layer 34 that contains a medium concentration of n-type impurities, and a low-concentration drift layer 36 that contains a low concentration of n-type impurities. In the present embodiment, the impurity concentration of the contact layer 32 is adjusted to 5×10¹⁹ cm⁻³, the impurity concentration of the drift layer 34 is adjusted to 5×10¹⁵ cm⁻³, and the impurity concentration of the low-concentration drift layer 36 is adjusted to 5×10¹⁴ cm⁻³. In addition, the thickness of the drift layer 34 is 5 μm, and the thickness of the low-concentration drift layer 36 is 3 μm. The thickness of the contact layer 32 is not specifically limited, and it may be, for example, several tens to several hundreds μm (typical wafer thickness).

The p+-type semiconductor regions 42 are formed in the semiconductor substrate 30. A relatively high concentration of p-type impurities is doped in the p+-type semiconductor regions 42. In the present embodiment, p-type impurities employ aluminum, and the concentration of the p-type impurities is adjusted to 1×10¹⁹ cm⁻³. As shown in FIG. 1 and FIG. 2, the p-type semiconductor regions 42 are formed in the low-concentration drift layer 36. The p-type semiconductor regions 42 are formed in a stripe in the transverse direction in the drawing. Thus, the low-concentration drift layer 36 and the p-type semiconductor region 42 are alternately exposed on the upper face 30a of the semiconductor substrate 30. The width W of each p-type semiconductor region 42 and the intervals S between the adjacent p-type semiconductor regions 42 are not specifically limited. In the present embodiment, the width W of each p-type semiconductor region 42 is 2 μm, and the intervals S between the adjacent p-type semiconductor regions 42 is 5 μm. In addition, the thickness of each p-type semiconductor region 42 is approximately 1.5 μm.

As shown in FIG. 1, the surfaces 42a of the p-type semiconductor regions 42 are recessed from the upper face 30a of the semiconductor substrate 30 and, therefore, the surfaces 42a of the p-type semiconductor regions 42 are lower in level than the surface 36a of the low-concentration drift layer 36. That is, there are steps between the surfaces 42a of the p-type semiconductor regions 42 and the surface 36a of the low-concentration drift layer 36. These steps are relatively small, and each have a size of approximately 100 nm in the present embodiment. Although it will be described later in detail, these steps are formed due to the method of manufacturing the semiconductor device 10. These steps are formed by removing the surface layer portions of the p-type semiconductor regions 42, which have a low impurity concentration due to outward diffusion in annealing treatment.

Next, the upper electrode 20 will be described. The upper electrode 20 may be broadly divided into a metal electrode portion 22 and 26 made of a metal material and semiconductor electrodes 24 made of a semiconductor material. The metal electrode portion 22 and 26 includes Schottky electrodes 22 made of molybdenum and a main metal electrode 26 made of aluminum. The main metal electrode 26 is formed on the Schottky electrodes 22 and the semiconductor electrodes 24. The main metal electrode 26 and the Schottky electrodes 22 are in ohmic contact with the semiconductor electrodes 24. The Schottky electrodes 22 are provided on the low-concentration drift layer 36 that is exposed on the upper face 30a of the semiconductor substrate 30. The Schottky electrodes 22 are made of a metal material, and are in Schottky contact with the low-concentration drift layer 36. The Schottky electrodes 22 may be, for example, made of titanium (Ti), molybdenum (Mo) or nickel (Ni). The Schottky electrodes 22 of the present embodiment are made of molybdenum.

The semiconductor electrodes 24 are provided on the p-type semiconductor regions 42 that are exposed on the upper face 30a of the semiconductor substrate 30. The semiconductor material, of the semiconductor electrodes 24 has a band gap narrower than that of 4H (or 6H) silicon carbide that forms the semiconductor substrate 30. The semiconductor electrodes 24 of the present embodiment are made of germanium-silicon. Here, the band gap of 4H silicon carbide (4H—SiC) is 3.2 eV, the band gap of 6H silicon carbide (6H—SiC) is 3.2 eV, and the band gap of germanium-silicon (SiGe) is 1.0 eV.

The lower electrode 50 is in ohmic contact with the contact layer 32 of the semiconductor substrate 30. The lower electrode 50 may employ the known structure of an ohmic contact electrode. The lower electrode 50 may be, for example, a laminated body of Ti/Ni/Au or a laminated body of NiSi/Ni/Au.

As described above, in the semiconductor device 10 of the present embodiment, the Schottky barrier diode structure 12 and the p-n diode structure 14 are alternately formed in one direction parallel to the substrate plane. Note that the Schottky barrier diode structure 12 is the range in which an n-type semiconductor region (low-concentration drift layer 36) is exposed on the upper face 30a of the semiconductor substrate 30 and in which the Schottky electrode 22 is formed in the upper electrode 20. On the other hand, the p-n diode structure 14 is the range in which the p-type semiconductor region 42 is exposed on the upper face 30a of the semiconductor substrate 30 and in which the semiconductor electrode 24 is formed in the upper electrode 20. When the semiconductor device 10 is reverse-biased (when the upper electrode 20 is at a low electric potential), depletion layers spread from pn junction planes between the p-type semiconductor regions 42 and the low-concentration drift layer 36 and then the low-concentration drift layer 36 that adjoins the Schottky electrodes 22 are depleted This improves occurrence of leakage current and low surge resistance in each Schottky barrier diode structure 12. On the other hand, when the semiconductor device 10 is forward-biased, a forward voltage drop (on-resistance) is suppressed by each Schottky barrier diode structure 12.

The semiconductor device 10 of the present embodiment includes the semiconductor electrodes 24 made of a material whose band gap is narrower than that of the semiconductor substrate 30. The metal electrode portion 22 and 26 of the upper electrode 20 is electrically continuous with the p-type semiconductor regions 42 through the semiconductor electrodes 24. By so doing, for example, in comparison with the case in which the metal electrode portion 22 and 26 is directly connected to the p-type semiconductor regions 42 made of molybdenum or aluminum, it is possible to reduce contact resistance between the upper electrode 20 and the p-type semiconductor regions 42. Particularly, in the present embodiment, because the semiconductor substrate 30 is made of silicon carbide that has a relatively wide band gap, the above effect, that is, reduction in contact resistance, is significantly large. For example, when the main metal electrode 26 made of aluminum is directly connected to the p-type semiconductor regions 42 made of silicon carbide, the barrier height at each junction plane is 2.5 eV, whereas when the semiconductor electrodes 24 made of germanium-silicon are connected to the p-type semiconductor regions 42 made of silicon carbide, the barrier height at each junction plane may be significantly reduced to 0.8 eV.

Furthermore, in the semiconductor device 10 of the present embodiment, the surface layer portions of the p-type semiconductor regions 42 are removed prior to the formation of the semiconductor electrodes 24 in the manufacturing method which will be described later. The surface layer portions of the p-type semiconductor regions 42 tend to decrease in impurity concentration because of outward diffusion. Then, when the impurity concentration is decreased at the surface layer portions of the p-type semiconductor regions 42, contact resistance between the p-type semiconductor regions 42 and the semiconductor electrodes 24 increase. Thus, by removing the surface layer portions of the p-type semiconductor regions 42 prior to the formation of the semiconductor electrodes 24, it is possible to prevent an increase in contact resistance between the p-type semiconductor regions 42 and the semiconductor electrodes 24. In this case, as in the case of the semiconductor device 10 of the present embodiment, the upper face 30a of the semiconductor substrate 30 has such a characteristic appearance that at least part of the surfaces 42a of the p-type semiconductor regions 42 are lower in level than the low-concentration drift layer 36 (steps are formed).

In addition, in the semiconductor device 10 of the present embodiment, two drift layers 34 and 36 having different impurity concentrations are formed in the semiconductor substrate 30. By so doing, the concentration of n-type impurities is relatively low around the p-type semiconductor regions 42, and the concentration of n-type impurities is relatively high at locations remote from the p-type semiconductor regions 42. When the concentration of n-type impurities is relatively low around the p-type semiconductor regions 42, depletion layers easily spread from the pn junction planes when the semiconductor device 10 is reverse-biased. For example, when the impurity concentration of the low-concentration drift layer 36 is set to 5×10¹⁵/cm³, the width by which each depletion layer spreads is 0.73 μm. Thus, the interval S between the adjacent p-type semiconductor regions 42 may be increased to 1.46 μm. Furthermore, when the impurity concentration of the low-concentration drift layer 36 is set to 5×10⁴/cm³, the width by which each depletion layer spreads is 2.31 μm. Thus, the interval S between the adjacent p-type semiconductor regions 42 may be increased to 4.62 μm. When the interval S between the adjacent p-type semiconductor regions 42 is increased, the area of each Schottky barrier diode structure 12 increases and, therefore, it is possible to suppress the on-resistance of the semiconductor device 10 to a lower value. However, when the impurity concentration of the semiconductor substrate 30 is decreased, the on-resistance of the semiconductor substrate 30 increases. For the above reasons, as in the case of the present embodiment, the impurity concentration of the semiconductor substrate 30 is varied in its thickness direction, the concentration of n-type impurities is relatively low around the p-type semiconductor regions 42, and the concentration of n-type impurities is relatively high at locations remote from the p-type semiconductor regions 42. Thus, it is possible to implement the semiconductor device 10 whose on-resistance is remarkably decreased.

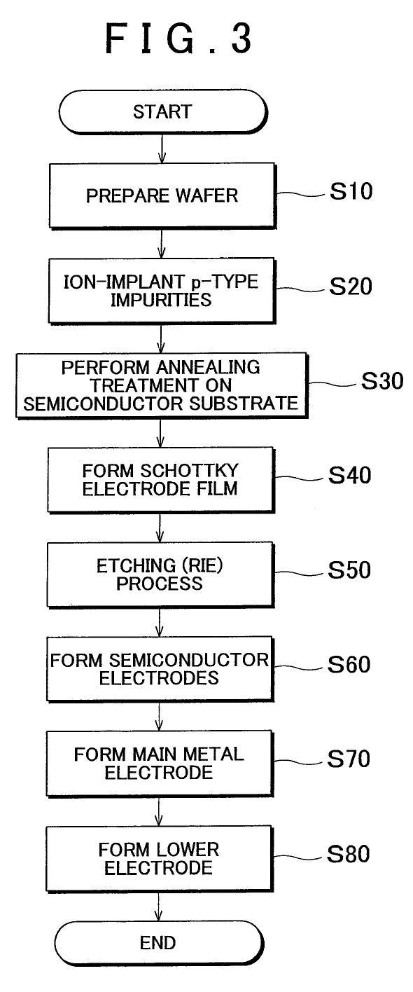

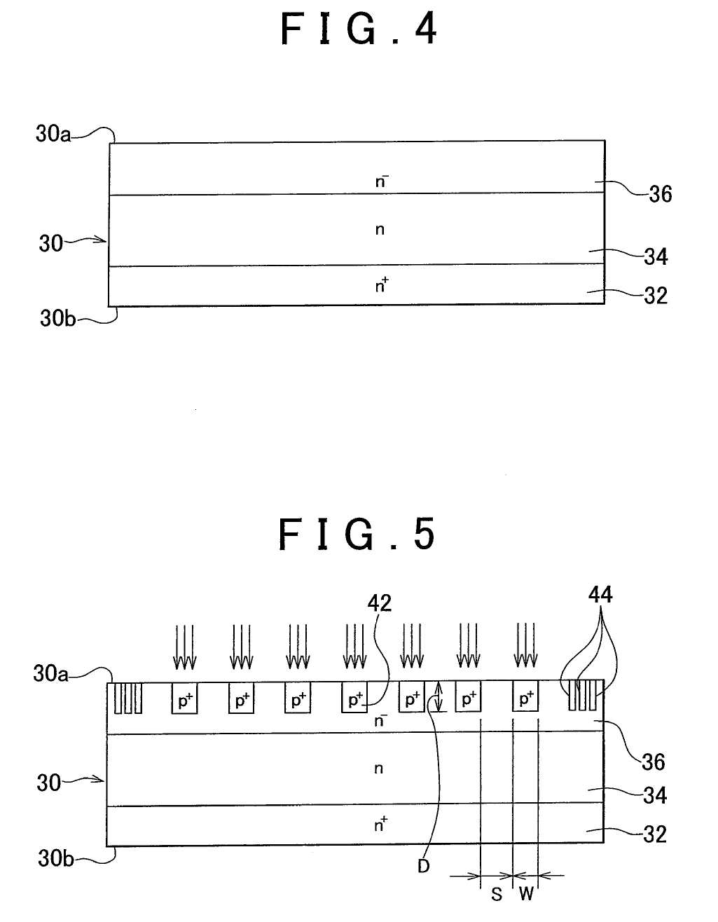

Next, the method of manufacturing the semiconductor device 10 will be described. FIG. 3 is a flowchart that shows the flow of the method of manufacturing the semiconductor device 10. Hereinafter, along the flowchart shown in FIG. 3, the method of manufacturing the semiconductor device 10 will be described in detail. First, in step S10, as shown in FIG. 4, the n-type semiconductor substrate 30 is prepared. The crystal structure of the semiconductor substrate 30 is desirably, for example, a hexagonal crystal (4H structure or 6H structure). The contact layer 32, the drift layer 34 and the low-concentration drift layer 36 are formed in the semiconductor substrate 30 in the order from the side adjacent to the lower face 30b. The contact layer 32 contains a high concentration of n-type impurities. The drift layer 34 contains a medium concentration of n-type impurities. The low-concentration drift layer 36 contains a low concentration of n-type impurities. The method of manufacturing the semiconductor substrate 30 is not specifically limited. In the present embodiment, an n-type silicon carbide wafer (4H structure), which will be the contact layer 32, is prepared, and then the drift layer 34 and the low-concentration drift layer 36 are sequentially formed by epitaxial crystal growth. Here, the impurity concentration of the silicon carbide wafer is 5×10¹⁹ cm³, the impurity concentration of the drift layer 34 is 5×10¹⁵ cm⁻³, and the impurity concentration of the low-concentration drift layer 36 is 5×10¹⁴ cm⁻³. In addition, the thickness of the drift layer 34 is 5 μm, and the thickness of the low-concentration drift layer 36 is 3 μm.

Next, in step S20 and in step S30, p-type impurities are doped into the semiconductor substrate 30 to thereby form the p-type semiconductor regions 42 and guard rings 44. First, in step S20, as shown in FIG. 5, aluminum, which is a p-type impurity, is ion-implanted from the upper face 30a of the semiconductor substrate 30. Subsequently, in step S30, annealing treatment in which the semiconductor substrate 30 is heated to about 1600° C. is performed. By so doing, the p-type semiconductor regions 42 and the guard rings 44 are formed to include diffused p-type impurities. As described above, the p-type semiconductor regions 42 are formed in a stripe (see FIG. 2). Thus, in the semiconductor substrate 30, the p-type semiconductor region and the n-type semiconductor region are alternately arranged in one direction parallel to the substrate plane. The impurity concentration, width W, interval S and depth D of the p-type semiconductor regions 42 may be appropriately set depending on characteristics required. In the present embodiment, the impurity concentration of each p-type semiconductor region 42 is set to 1×10¹⁹ cm⁻³, the width W is set to 2 μm, the interval S is set to 5 μm, and the depth D is set to 1.5 μm. In the present embodiment, the interval S between the adjacent p-type semiconductor regions 42 is formed so as to be wider than the width W of each p-type semiconductor region 42 to thereby increase the area of each Schottky barrier diode structure 12.

The formation pattern of the p-type semiconductor regions 42 is not limited to stripes. For example, the p-type semiconductor regions 42 may be formed in a lattice pattern or may be formed in a honeycomb pattern. When the p-type semiconductor regions 42 are formed in a lattice pattern, the p-type semiconductor region and the n-type semiconductor region are alternately arranged in two directions parallel to the substrate plane in the semiconductor substrate 30. When the p-type semiconductor regions 42 are formed in a honeycomb pattern, the p-type semiconductor region and the n-type semiconductor region are alternately arranged in three directions parallel to the substrate plane in the semiconductor substrate 30. The formation pattern of the p-type semiconductor regions 42 may employ various patterns that implement a so-called super junction structure.

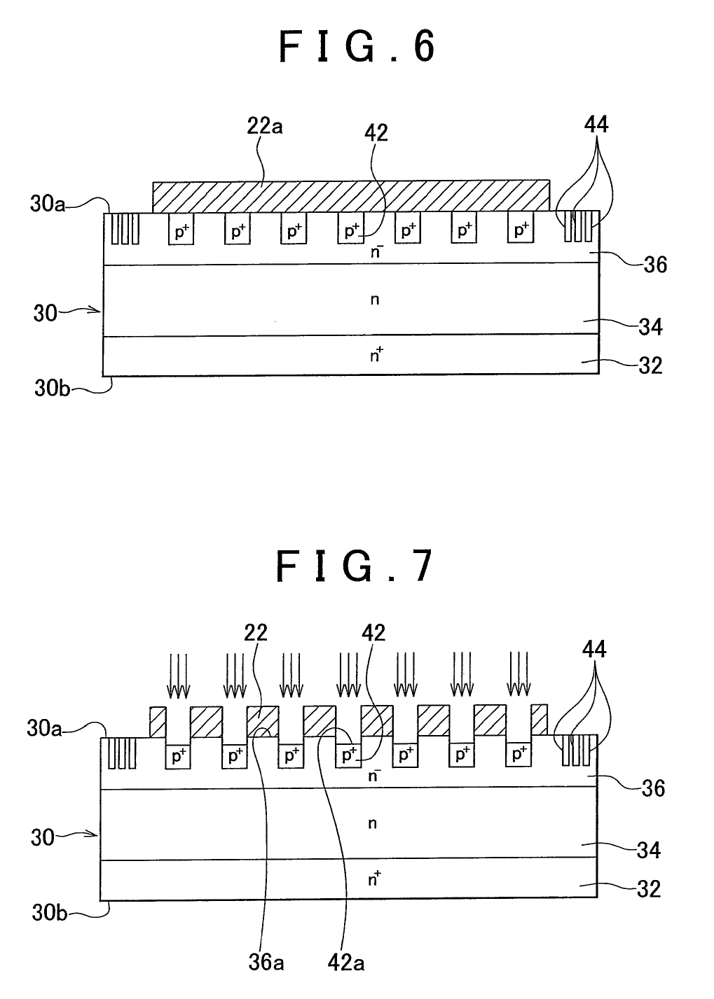

Next, in step S40, as shown in FIG. 6, a Schottky electrode film 22a is formed on the upper face 30a of the semiconductor substrate 30. The Schottky electrode film 22a is a metal film which will be the Schottky electrodes 22 in the present embodiment, a molybdenum film is formed as the Schottky electrode film 22a. The Schottky electrode film 22a may be, for example, formed by vacuum evaporation. Next, in step S50, as shown in FIG. 7, reactive ion etching (RIE) is performed to thereby remove the Schottky electrode film 22a formed on the p-type semiconductor regions 42. By so doing, the Schottky electrodes 22 are formed so as to be in Schottky contact with the low-concentration drift layer 36. Furthermore, in the reactive ion etching in step S50, the surface layer portions of the p-type semiconductor regions 42 are also removed together with the Schottky electrode film 22a located on the p-type semiconductor region 42. The surface layer portions of the p-type semiconductor regions 42 are removed continuously to the removal of the Schottky electrode film 22a. The surface layer portions of the p-type semiconductor regions 42 may be, for example, removed to the depth of 100 nm. By removing the surface layer portions of the p-type semiconductor regions 42, the surfaces 42a of the p-type semiconductor regions 42 are recessed from the upper face 30a of the semiconductor substrate 30, and then steps are formed between the surfaces 42a of the p-type semiconductor regions 42 and the surfaces 36a of the low-concentration drift layers 36.

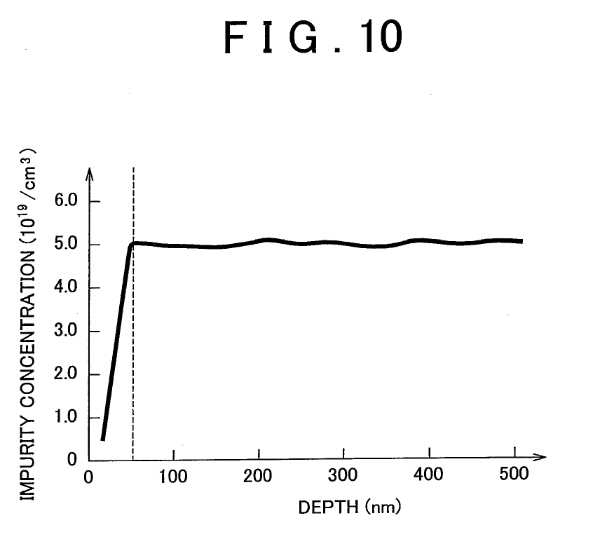

Here, the reason why the surface layer portions of the p-type semiconductor regions 42 are removed will be described. In the annealing treatment of step S30 described above, the semiconductor substrate 30 is heated to a high temperature and activated. The activated semiconductor substrate 30 incorporates the ion-implanted p-type impurities (aluminum) into the crystals of the semiconductor substrate 30. At this time, outward diffusion, in which p-type impurities that are discharged outward, occurs at the surface layer portions of the p-type semiconductor regions 42. As a result, as show in FIG. 10, the surface layer portions (shallow range from the upper face 30a of the semiconductor substrate 30 to the depth of several tens nm) of the p-type semiconductor regions 42 have a low concentration of impurities. When the surface layer portions of the p-type semiconductor regions 42 have a low concentration of impurities, contact resistance between the p-type semiconductor regions 42 and the semiconductor electrodes 24, which will be formed later, increase. For this reason, the surface layer portions of the p-type semiconductor regions 42 are removed after the annealing treatment in step S30. Thus, it is possible to prevent an increase in contact resistance between the p-type semiconductor regions 42 and the semiconductor electrodes 24.

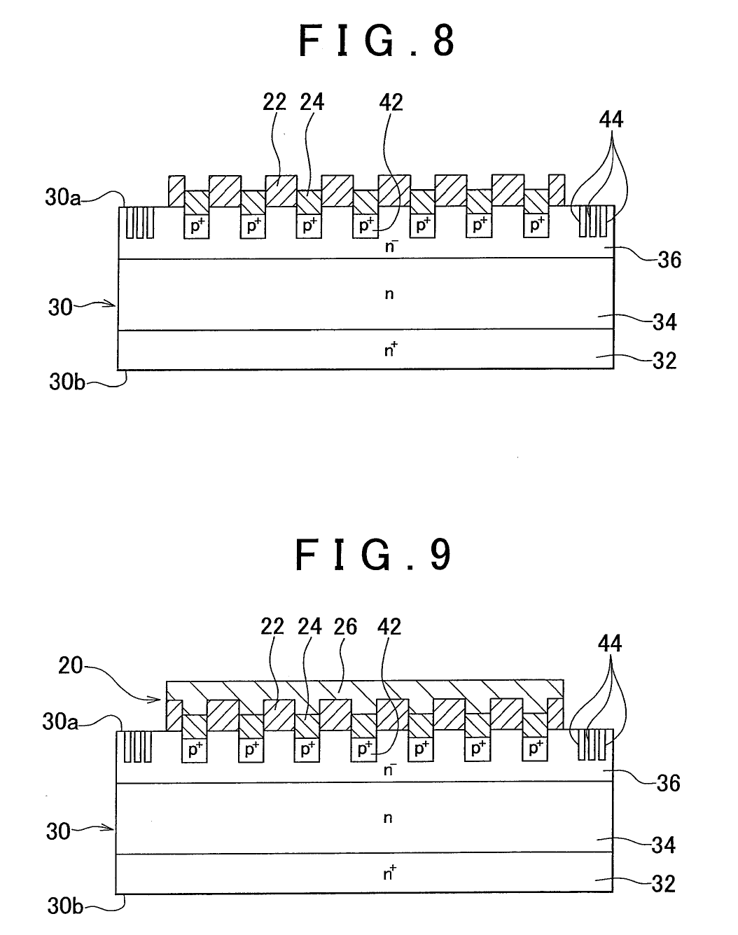

Next, in step S60, as shown in FIG. 8, the semiconductor electrodes 24 made of germanium-silicon are formed on the p-type semiconductor regions 42 that are exposed on the upper face 30a of the semiconductor substrate 30. Note that the material of the semiconductor electrodes 24 is desirably germanium-silicon; instead, as described above, another semiconductor material whose band gap is narrower than that of the material of the semiconductor substrate 30 (here, 4H silicon carbide) may also be employed. The semiconductor electrodes 24 may be, for example, formed by chemical vapor deposition (CVD) in an atmosphere of 400° C. In addition, the thickness of each semiconductor electrode 24 may be, for example, set to 300 nm. The semiconductor electrodes 24 are formed on the p-type semiconductor regions 42 after the surface layer portions have been removed (step S50). By so doing, it is possible to relatively reduce the contact resistance between the semiconductor electrodes 24 and the p-type semiconductor regions 42.

Next, in step S70, as shown in FIG. 9, the main metal electrode 26 made of aluminum is formed on the Schottky electrodes 22 and semiconductor electrodes 24. Note that the material of the main metal electrode 26 is not limited to aluminum; instead, another metal material may be used. The main metal electrode 26 may be, for example, formed by sputtering. In addition, the thickness of the main metal electrode 26 may be, for example, set to 3 μm. Finally, in step S80, the lower electrode 50 is formed to thereby obtain the structure of the semiconductor device 10 shown in FIG. 1.

Specific embodiments of the invention are described in greater detail above; these are only illustrative and do not limit the scope of the appended claims. The scope of the claims also encompasses various modifications and alterations to the above illustrated specific embodiments. The technical elements described in the specification and drawings are technically advantageous either alone or in various combinations, and are not limited to combinations recited in claims at the time of filing the application. In addition, the technologies illustrated in the specification or drawings achieve multiple objects at the same time; and it is also technically advantageous when one of the multiple objects is achieved.

While the invention has been described with reference to exemplary embodiments thereof, it is to be understood that the invention is not limited to the exemplary embodiments or constructions. To the contrary, the invention is intended to cover various modifications and equivalent arrangements. In addition, while the various elements of the exemplary embodiments are shown in various combinations and configurations, which are exemplary, other combinations and configurations, including more, less or only a single element, are also within the spirit and scope of the invention.

What is claimed is:

1. A semiconductor device comprising:
an n-type semiconductor substrate; and
an upper electrode formed on an upper face of the semiconductor substrate, wherein
a p-type semiconductor region is repeatedly formed in the semiconductor substrate in at least one direction parallel to the substrate plane so as to be exposed on an upper face of the semiconductor substrate,
the upper electrode includes a metal electrode portion made of a metal material; and a semiconductor electrode portion made of a semiconductor material whose band gap is narrower than that of the semiconductor substrate,
the semiconductor electrode portion is provided on each p-type semiconductor region that is exposed on the upper face of the semiconductor substrate, and
the metal electrode portion is in Schottky contact with an n-type semiconductor region that is exposed on the upper face of the semiconductor substrate, and is in ohmic contact with the semiconductor electrode portion.

2. The semiconductor device according to claim 1, wherein
the semiconductor substrate is made of silicon carbide.

3. The semiconductor device according to claim 2, wherein
the semiconductor electrode portion is made of germanium-silicon.

4. The semiconductor device according to claim 1, wherein
the semiconductor electrode portion is made of germanium-silicon.

5. The semiconductor device according to claim 1, wherein
at least part of a surface of each p-type semiconductor region is recessed from the upper face of the semiconductor substrate.

6. The semiconductor device according to claim 1, wherein
the semiconductor substrate includes, in the order from a side adjacent to a lower face of the semiconductor substrate, a high-concentration n-type semiconductor layer that contains a high concentration of n-type impurities; a medium-concentration n-type semiconductor layer that contains a medium concentration of n-type impurities; and a low-concentration n-type semiconductor layer that contains a low concentration of n-type impurities, and
each p-type semiconductor region is formed in the low-concentration n-type semiconductor layer of the semiconductor substrate.

7. A method of manufacturing a semiconductor device, comprising:
a substrate preparation step of preparing an n-type semiconductor substrate;
a p-type region formation step of forming a p-type semiconductor region repeatedly in the semiconductor substrate in at least one direction parallel to the substrate plane so as to be exposed on an upper face of the semiconductor substrate; and
an electrode formation step of forming an upper electrode on the upper face of the semiconductor substrate, wherein
the upper electrode includes a metal electrode portion made of a metal material; and a semiconductor electrode portion made of a semiconductor material whose band gap is narrower than that of the semiconductor substrate,
the semiconductor electrode portion is provided on each p-type semiconductor region that is exposed on the upper face of the semiconductor substrate, and
the metal electrode portion is in Schottky contact with an n-type semiconductor region that is exposed on the upper face of the semiconductor substrate, and is in ohmic contact with the semiconductor electrode portion.

8. The method of manufacturing a semiconductor device according to claim 7, wherein
the electrode formation step includes a metal electrode film formation step of forming a metal electrode film, which is at least part of the metal electrode portion, on the upper face of the semiconductor substrate; an etching step of removing the metal electrode film formed on each p-type semiconductor region that is exposed on the upper face of the semiconductor substrate; and a semiconductor electrode formation step of forming the semiconductor electrode portion on each p-type semiconductor region that is exposed on the upper face of the semiconductor substrate, and
in the etching step, at least part of a surface layer portion of each p-type semiconductor region is further removed continuously to the removal of the metal electrode film.
